(19) United States
(12) Patent Application Publication
(10) Pub. No.: US 2025/0061957 A1
(43) Pub. Date: Feb. 20, 2025

(54) MEMORY DEVICE AND MEMORY TEST SYSTEM THEREOF

(71) Applicant: Samsung Electronics Co., Ltd., Suwon-si (KR)

(72) Inventors: Seokwoo Lee, Suwon-si (KR); HOONJIN BANG, Suwon-si (KR); SEEUN OH, Suwon-si (KR)

(21) Appl. No.: 18/581,736

(22) Filed: Feb. 20, 2024

(30) Foreign Application Priority Data
Aug. 16, 2023 (KR) 10-2023-0107047

(51) Int. Cl. G11C 29/12

(52) U.S. Cl. CPC G11C 29/12; G11C 2029/1204

(57) ABSTRACT

A memory device according to embodiments of the present disclosure includes a first memory cell including a first electrical fuse and a first program transistor connected in series between a first bitline and a ground voltage node, a second memory cell including a second electrical fuse and a second program transistor connected in series between the first bitline and the ground voltage node, and a first test cell including a first test transistor connected between the first bitline and the ground voltage node.

### CROSS-REFERENCE TO RELATED APPLICATION

This application claims priority to and the benefit of Korean Patent Application No. 10-2023-0107047 filed in the Korean Intellectual Property Office on Aug. 16, 2023, the entire contents of which are incorporated herein by reference.

### BACKGROUND

### (a) FIELD

The present disclosure relates to a semiconductor memory device. More specifically, the present disclosure relates to a memory device and a test system thereof.

### (b) Description

A one-time programmable (OTP) memory device may include a plurality of OTP memory cells including an electrical fuse (efuse). The OTP memory device may store data based on whether an electrical fuse is blown. For example, an OTP memory cell including a blown electrical fuse may store data corresponding to ‘l’, and an OTP memory cell including an unblown electrical fuse may store data corresponding to ‘0’.

Whether data is stored in the OTP memory cell as intended may be tested by measuring a resistance value of an electrical fuse included in the OTP memory cell. However, as memory devices tend to be highly integrated, it is becoming increasingly difficult to accurately measure the resistance of an electrical fuse.

### SUMMARY

The embodiments of the present disclosure address the above-mentioned technical issues. More specifically, embodiments disclosed herein relate to a memory device configured to more accurately measure a resistance value of an electrical fuse and a test system thereof.

A memory device according to an embodiment of the present disclosure includes a first memory cell including a first electrical fuse and a first program transistor connected in series between a first bitline and a ground voltage node, a second memory cell including a second electrical fuse and a second program transistor connected in series between the first bitline and the ground voltage node, and a first test cell including a first test transistor connected between the first bitline and the ground voltage node.

A test system according to an embodiment of the present disclosure includes a memory device including a first memory cell connected to a first word line and a first bitline, a first test cell connected to a first dummy word line and the first bitline, and a power supply pad connected to the first bitline, and a test device configured to measure a first current provided to the power supply pad in response to activation of the first word line and the first bitline, a second current provided to the power supply pad in response to activation of the first dummy word line and the first bitline, and a third current provided to the power supply pad in response to activation of the first bitline.

A memory device according to an embodiment of the present disclosure includes a memory cell array including a plurality of memory cells connected to a first bitline, and a test cell array including a first test cell and a second test cell connected to the first bitline. The first test cell includes a first test transistor including a first drain terminal electrically connected to the first bitline, and a first source terminal connected to a ground voltage node, the second test cell includes a second test transistor including a second drain terminal not electrically connected to the first bitline, and a second source terminal connected to the ground voltage node.

### BRIEF DESCRIPTION OF THE DRAWINGS

FIG. 1 is a block diagram illustrating a test system according to an embodiment of the present disclosure.

FIG. 2 is a block diagram illustrating the memory device of FIG. 1 in more detail, according to an embodiment of the present disclosure.

FIG. 3 is a diagram illustrating some configurations of FIG. 2 in more detail, according to an embodiment of the present disclosure.

FIG. 4 is a diagram illustrating some configurations of FIG. 3 in more detail, according to an embodiment of the present disclosure.

FIG. 5 is a diagram illustrating a method in which the test apparatus of FIG. 1 measures resistance of an electrical fuse included in the memory cell of FIG. 4 according to some embodiments.

FIG. 6 is a diagram describing a measurement error when the test apparatus of FIG. 1 measures the resistance of an electrical fuse included in the memory cell of FIG. 4.

FIG. 7 is a diagram illustrating the operation of a test system according to an embodiment of the present disclosure.

FIG. 8 is a diagram illustrating the operation of a test system according to an embodiment of the present disclosure.

FIG. 9 is a diagram illustrating the operation of a test system according to an embodiment of the present disclosure.

FIG. 10 is a diagram illustrating the operation of a test system according to an embodiment of the present disclosure.

FIG. 11 is a schematic view illustrating a first bitline and test cells of FIG. 4 implemented according to an embodiment.

FIGS. 12A and 12B are cross-sectional views illustrating a connection relationship between the first bitline and test cells of FIG. 11 in more detail, implemented according to an embodiment.

FIG. 13 is a flowchart illustrating the operation of the test apparatus of FIG. 1.

FIG. 14 is a diagram illustrating some configurations of FIG. 2 implemented according to an embodiment in more detail.

FIG. 15 is a diagram illustrating some configurations of FIG. 14 in more detail, according to an embodiment of the present disclosure.

FIG. 16 is a diagram illustrating first to third current measurement methods when a memory device is implemented according to the embodiment of FIG. 14.

FIG. 17 is a block diagram illustrating the memory device of FIG. 1 according to an embodiment.

FIG. 18 is a block diagram illustrating a memory system including the memory device of FIG. 1, according to an embodiment of the present disclosure.

FIG. 19 is a block diagram illustrating the memory device of FIG. 18 in more detail, according to an embodiment of the present disclosure.

FIG. 20 is a diagram illustrating some configurations of FIG. 19 in more detail, according to an embodiment of the present disclosure.

FIG. 21 is a circuit diagram illustrating a configuration of one of the memory cells of FIG. 20 in more detail, according to an embodiment of the present disclosure.

FIG. 22 is a circuit diagram illustrating the configuration of the test cell of FIG. 20 in more detail.

FIG. 23 is a circuit diagram illustrating a configuration of one of bitline select switches of FIG. 20 in more detail, according to an embodiment of the present disclosure.

### DETAILED DESCRIPTION

Hereinafter, the present disclosure will be described in detail with reference to the accompanying drawings, in which embodiments of the present disclosure are shown. In the description below, details such as detailed configurations and structures are simply provided to help overall understanding. Therefore, without departing from the technical idea and scope of the present disclosure, modifications on embodiments described in this specification may be performed by those skilled in the art. Furthermore, descriptions of well-known functions and structures are omitted for clarity and conciseness. Configurations in drawings or detailed description below may be shown in the drawings or may be connected with another component other than components described in the detailed description. The terms used herein are defined in consideration of the functions of the inventive concept and are not limited to specific functions. The definition of terms may be determined based on the details described in the detailed description. Constituent elements described with reference to terms such as a unit, a driver, or a block used in the detailed description may be implemented in software, hardware, or a combination thereof. Exemplarily, software may be machine code, firmware, embedded code, and application software. For example, hardware may include an electrical circuit, an electronic circuit, a processor, a computer, integrated circuit cores, a pressure sensor, an inertial sensor, micro electro mechanical systems (MEMS), a passive device, or a combination thereof.

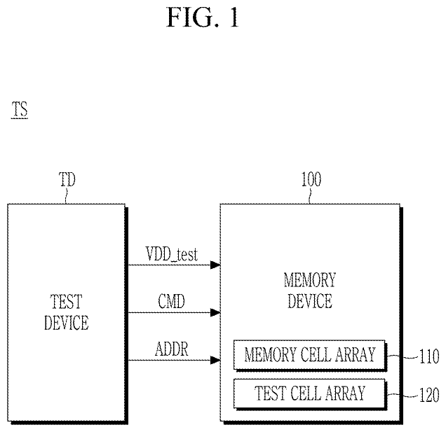

FIG. 1 is a block diagram illustrating a test system according to an embodiment of the present disclosure. Referring to FIG. 1, a test system TS may include a test device TD and a memory device 100.

The memory device 100 may be, for example, a semiconductor chip or semiconductor package, and may include a memory cell array 110. The memory cell array 110 may include a plurality of memory cells. Each of the plurality of memory cells may be an OTP memory cell implemented based on an electrical fuse (efuse). In this case, each of the plurality of memory cells may store data based on whether an electrical fuse is blown or a resistance value of the electrical fuse.

For more concise description, an embodiment in which the memory device 100 is an OTP memory device implemented based on an electrical fuse (efuse) will be representatively described below. However, the scope of the present disclosure is not limited thereto, and the memory device 100 may be any type of non-volatile memory device.

The test device TD may control the memory device 100 by transmitting the command CMD and/or the address ADDR to the memory device 100. The test device TD may therefore include logic and other circuitry and may be a controller, processor, semiconductor chip and/or other hardware-based device configured to perform testing of the memory device 100.

The test device TD may provide a test power source voltage VDD_test to the memory device 100. The memory device 100 may perform an operation corresponding to the received command CMD and/or address ADDR based on the test power source voltage VDD_test.

In an embodiment, the test power source voltage VDD_test may have a voltage level sufficiently low so that an electrical fuse included in a memory cell is not blown. For example, the test power source voltage VDD_test may have a voltage level less than ‘IV’. In an embodiment, the test power source voltage VDD_test may be about ‘0.1V’.

In an embodiment, the test power source voltage VDD_test may be provided to the memory device 100 through a power supply pad (not shown). That is, the memory device 100 may receive the test power source voltage VDD_test from the test device TD through a power supply pad (not shown).

The test device TD may measure a resistance value of an electrical fuse included in each of a plurality of memory cells of the memory device 100. For example, the test device TD may sequentially activate each memory cell by sequentially providing an address ADDR for each of a plurality of memory cells. The test device TD may measure the size of current provided to a power supply pad (not shown) of the memory device 100 in response to activation of each memory cell. That is, the test device TD may measure the resistance value of the electrical fuse included in each of the plurality of memory cells based on the size of current required to supply the test power source voltage VDD_test to the memory device 100.

However, an error may be included in the resistance value of the electrical fuse measured by the test device TD. For example, the current provided to the power supply pad (not shown) measured by the test device TD may include errors due to various components, such as a leakage current in the memory device 100, a metal resistance, and a transistor-on-resistance. Therefore, an error may occur between the resistance value of the electrical fuse measured by the test device TD and the actual resistance value of the electrical fuse. Hereinafter, the configuration and operation of a test system TS that minimizes such a measurement error will be described.

The memory device 100 may include a test cell array 120. The test cell array 120 may include a plurality of test cells. The test device TD may control a plurality of test cells by transmitting the command CMD and/or the address ADDR to the memory device 100.

The test device TD may control the test cell array 120 to more accurately measure a resistance value of an electrical fuse included in each of the plurality of memory cells. For example, the test device TD may compensate for the size of the current measured as the memory cell is activated based on the size of the current provided to a power supply pad (not shown) measured as the test cell is activated. In this case, since the resistance value of the electrical fuse included in each of the plurality of memory cells may be more accurately measured, the test accuracy of the test device TD may be improved. A specific operation of the test device TD will be described in more detail with reference to the following drawings.

In an embodiment, each of the plurality of test cells does not include an electrical fuse. That is, each of the plurality of test cells may not store data. However, the scope of the present disclosure is not limited thereto. The configuration of the test cell will be described in detail with reference to the following drawings.

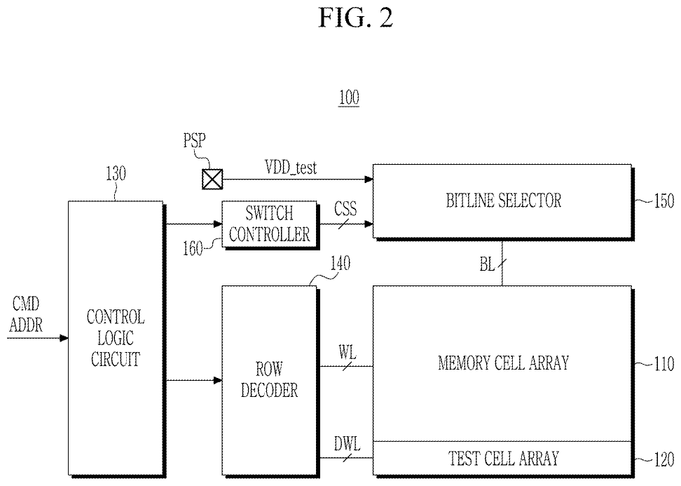

FIG. 2 is a block diagram illustrating the memory device of FIG. 1 in more detail. Referring to FIGS. 1 and 2, the memory device 100 may include a memory cell array 110, a test cell array 120, a control logic circuit 130, a row decoder 140, a bitline selector 150, a switch controller 160 and a power supply pad (PSP).

The memory cell array 110 may include a plurality of memory cells. The plurality of memory cells may be connected to a plurality of word lines WL extending in a row direction and a plurality of bitlines BL extending in a column direction.

The test cell array 120 may include a plurality of test cells. The plurality of test cells may be connected to a plurality of dummy word lines DWL extending in a row direction and a plurality of bitlines BL extending in a column direction. The dummy word lines DWL are considered “dummy” lines because they are not connected to memory cells, and therefore they are not used to store data to the cells that they are connected to.

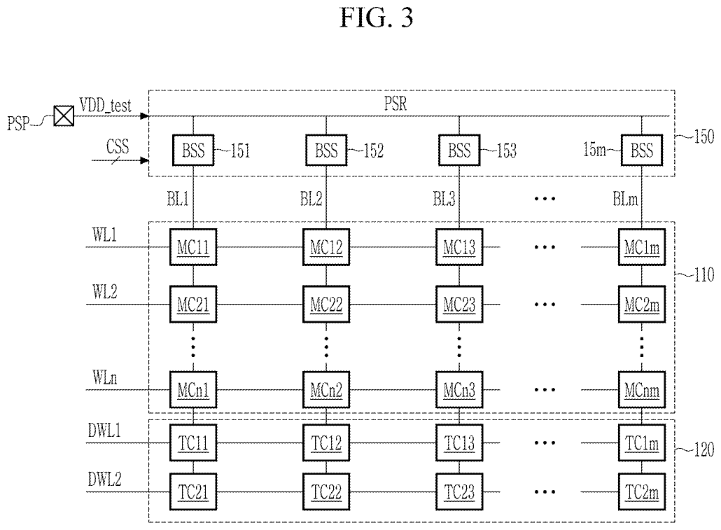

That is, the memory cell array 110 and the test cell array 120 may be connected to the same bitlines. For example, the memory cell array 110 and the test cell array 120 may share bitlines. A detailed implementation method of the memory cell array 110 and the test cell array 120 will be described with reference to FIG. 3 below.

The control logic circuit 130 may control overall operations of the memory device 100 based on the command CMD and address ADDR provided from the test device TD. For example, the control logic circuit 130 may control operations of the row decoder 140 and the switch controller 160 based on the command CMD and the address ADDR.

The row decoder 140 may control the plurality of word lines WL and the plurality of dummy word lines DWL based on the address ADDR. For example, the row decoder 140 may activate one of the plurality of word lines WL and the plurality of dummy word lines DWL based on the address ADDR.

The bitline selector 150 may be connected to the plurality of bitlines BL. The bitline selector 150 may receive the test power source voltage VDD_test from the test device TD through the power supply pad PSP.

The bitline selector 150 may include a plurality of bitline select switches (not shown). One end of each of the plurality of bitline select switches (not shown) may receive the test power source voltage VDD_test, and the other end of each of the plurality of bitline select switches (not shown) may be connected to bitlines different from each other.

The switch controller 160 may control the bitline selector 150 in response to control of the control logic circuit 130. For example, the switch controller 160 may provide a column select signal CSS created based on the address ADDR to the bitline selector 150. The bitline selector 150 may provide the test power source voltage VDD_test to a bitline corresponding to the column select signal CSS. For example, the bitline selector 150 may turn on a bitline select switch (not shown) corresponding to the column select signal CSS. In this case, the test power source voltage VDD_test will be provided to the corresponding bitline.

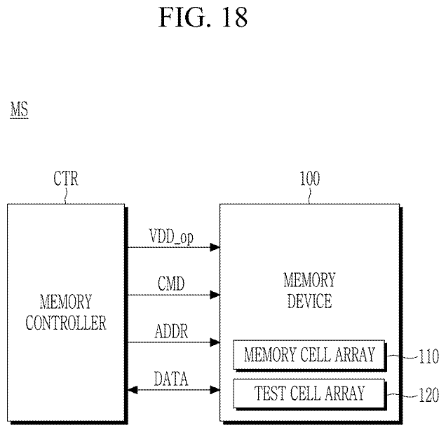

Hereinafter, for a more concise description, a test operation for internal resistance of the memory device 100 will be mainly described. An embodiment in which a read operation and a write operation for the memory device 100 are performed will be described in detail with reference to FIGS. 18 to 22 below.

FIG. 3 is a diagram illustrating some configurations of FIG. 2 in more detail.

Referring to FIGS. 1 to 3, the memory cell array 110 may include a plurality of memory cells MC. The plurality of memory cells MC may be arranged in a row direction and a column direction to form a matrix structure.

The plurality of memory cells MC may be connected to first to nth word lines WL1 to WLn. The plurality of memory cells MC may be connected to first to mth bitlines BL1 to BLm. Hereinafter, for more concise description, a memory cell connected to (i)th word line and (j)th bitline will be referred to as a memory cell MCij. For example, a memory cell connected to a second word line WL2 and the first bitline BL1 will be referred to as a memory cell MC21. However, the scope of the present disclosure is not limited thereto.

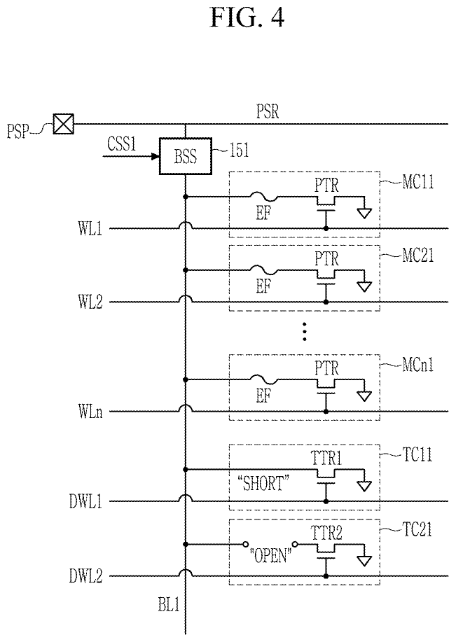

Each of the plurality of memory cells MC may include an electrical fuse. Each of the plurality of memory cells MC may store data based on whether an electrical fuse is blown. A more detailed configuration of each of the plurality of memory cells MC will be described in detail with reference to FIG. 4 below.

The test cell array 120 may include a plurality of test cells TC. The plurality of test cells TC may be arranged in a row direction and a column direction to form a matrix structure.

The plurality of test cells TC may be connected to first and second dummy word lines DWL1 to DWL2. The plurality of test cells TC may be connected to the first to mth bitlines BL1 to BLm. Hereinafter, for more concise description, a test cell connected to a (i)th dummy word line and a (j)th bitline will be referred to as a test cell TCij. For example, a test cell connected to a first dummy word line DWL1 and a second bitline BL2 will be referred to as a test cell TC12. However, the scope of the present disclosure is not limited thereto.

Each of the plurality of test cells TC may not include an electrical fuse. A more detailed configuration of each of the plurality of test cells TC will be described in detail with reference to FIG. 4 below.

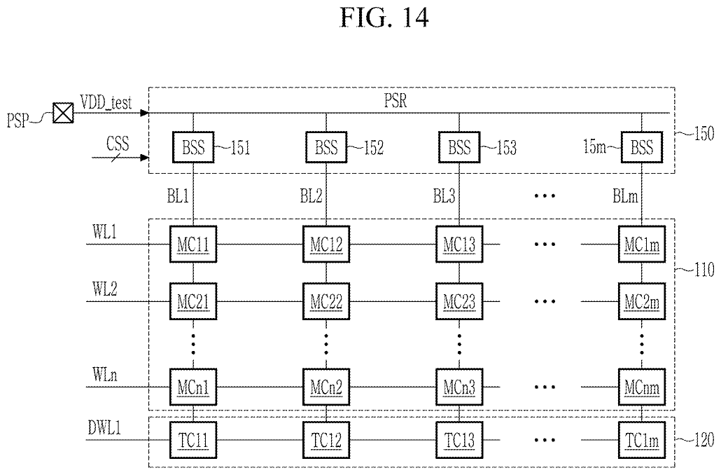

Hereinafter, for more concise description, an embodiment in which the test cell array 120 is connected to two dummy word lines (i.e., the first dummy word line DWL1 and a second dummy word line DWL2) will be representatively described. However, the scope of the present disclosure is not limited thereto. For example, the test cell array 120 may be configured to be connected to one dummy word line. An embodiment in which the test cell array 120 is connected to one dummy word line will be described in more detail with reference to FIGS. 14 to 16 below.

The bitline selector 150, also described as a bitline selector circuit, may include first to mth bitline select switches 151 to 15m. First ends of the first to mth bitline select switches 151-15m may be connected to first to mth bitlines BL1 to BLn, respectively. Second, opposite, ends of the first to m-th bitline select switches 151 to 15m may be connected to a power supply rail PSR.

The bitline selector 150 may connect a corresponding bitline to the power supply rail PSR in response to the column select signal CSS. For example, the first to mth bitline select switches 151 to 15m may be turned on or off in response to different column select signals, respectively.

For a more detailed example, the switch controller 160 may output a first column select signal CSS1 for controlling the first bitline BL1 in response to the address ADDR corresponding to the first bitline BL1. In this case, the first bitline select switch 151 may connect the first bitline BL1 to the power supply rail PSR in response to the first column select signal CSS1. However, the scope of the present disclosure is not limited thereto.

The power supply rail PSR may be connected to the power supply pad PSP. The power supply rail PSR may receive a constant level of voltage from the power supply pad PSP. For example, the voltage level of the power supply rail PSR may be maintained at the test power source voltage VDD_test. However, the size of the current flowing through the power supply pad PSP to the power supply rail PSR may be variable. For example, the size of current flowing through the power supply pad PSP to the power supply rail PSR may vary depending on which memory cell (or test cell) is activated.

For a more concise description, FIG. 3 shows an embodiment in which the memory cell array 110 is disposed adjacent to the power supply rail PSR and the test cell array 120 is disposed spaced apart from the power supply rail PSR, the scope of the present disclosure is not limited thereto. That is, the scope of the present disclosure will not be limited to a position where the test cell array 120 is disposed.

FIG. 4 is a diagram illustrating some configurations of FIG. 3 in more detail.

Hereinafter, configurations of memory cells MC11 to MCnl and test cells TC11 to TC21 connected to the first bitline BL1 of FIG. 3 will be representatively described. However, the scope of the present disclosure is not limited thereto, and memory cells and test cells connected to the second to m-th bitlines BL2 to BLm may also be configured similarly.

Referring to FIGS. 1 to 4, a first bitline select switch 151 may connect the power supply rail PSR and the first bitline BL1 in response to the first column select signal CSS1. For example, the first bitline select switch 151 may be turned on in response to the first column select signal CSS1 having a logic high level.

Each of the memory cells MC11 to MCnl connected to the first bitline BL1 may include an electrical fuse EF and a program transistor PTR. Each of the memory cells MC11 to MCnl may operate in response to a voltage level of a connected word line. For example, the program transistor PTR included in the memory cell MC11 may operate in response to the voltage level of the first word line WL1. That is, the gate terminal of the program transistor PTR included in the memory cell MC11 may be connected to the first word line WL1.

The electrical fuse EF and the program transistor PTR included in each of the memory cells MC11 to MCnl may be connected in series between the first bitline BL1 and the ground voltage. The ground voltage may be supplied, for example, to a ground voltage node configured to receive a ground voltage either from outside of the memory device or from within the memory device. All conductive pads, lines, or other elements (e.g., connection terminals) configured to be connected to ground voltage may be included in the ground voltage node. For example, one end of the electrical fuse EF included in the memory cell MC11 may be connected to the first bitline BL1, and the other end may be connected to the drain terminal of the program transistor PTR. A source terminal of the program transistor PTR included in the memory cell MC11 may be connected to the ground voltage. However, the scope of the present disclosure is not limited to a specific connection method of the electrical fuse EF and the program transistor PTR. For example, the electrical fuse EF may be connected between the source terminal of the program transistor PTR and the ground voltage. However, hereinafter, for more concise description, an embodiment in which the electrical fuse EF is connected between the bitline and the drain terminal of the program transistor will be representatively described.

Each of the memory cells MC11 to MCnl may store data based on whether the electrical fuse EF is blown. For example, a memory cell including a blown electrical fuse EF may store data corresponding to ‘l’ or logic high, and a memory cell including an unblown electrical fuse EF may store data corresponding to ‘0’ or logic low. However, the scope of the present disclosure is not limited thereto.

In an embodiment, the resistance value of the blown electrical fuse EF may be about 50 ohms, and the resistance value of the unblown electrical fuse EF may be about 10000 ohms. However, the scope of the present disclosure is not limited thereto.

Each of the test cells TC11 to TC21 connected to the first bitline BL1 may include a test transistor TTR. For example, the test cell TC11 may include a first test transistor TTR1, and the test cell TC12 may include a second test transistor TTR2. Hereinafter, for more concise description, the test cell TC11 may be referred to as a first test cell TC11, and the test cell TC12 may be referred to as a second test cell TC12.

In some embodiments, each of the first and second test cells TC11 to TC21 does not include an electrical fuse EF. Therefore, each of the first and second test cells TC11 to TC21 may not store data.

The first test cell TC11 may operate based on the voltage level of the first dummy word line DWL1. For example, a gate terminal of the first test transistor TTR1 may be connected to the first dummy word line DWL1.

The first test transistor TTR1 may be connected between the first bitline BL1 and the ground voltage. In one embodiment, the drain terminal of the first test transistor TTR1 and the first bitline BL1 may be directly electrically connected. For example, the drain terminal of the first test transistor TTR1 and the first bitline BL1 may be electrically shorted. As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through separate circuit elements such as resistors, capacitors, fuses, transistors, or diodes.

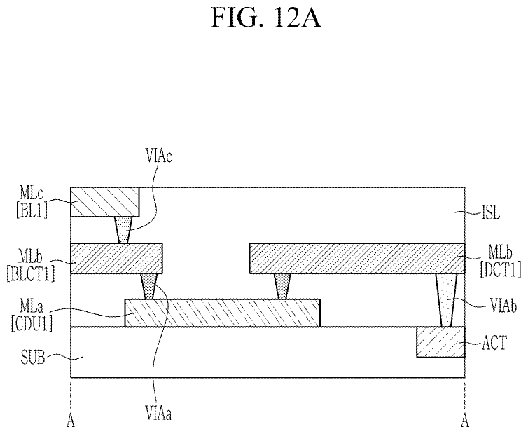

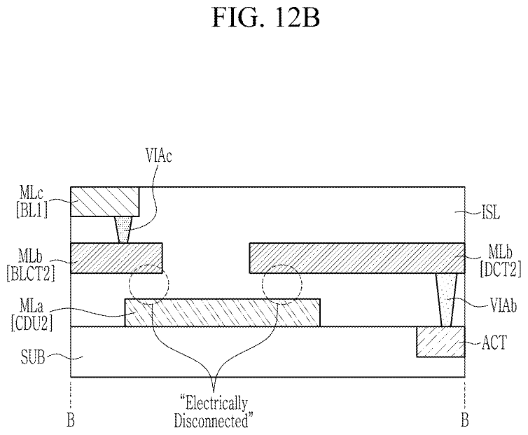

In an embodiment, the first test transistor TTR1 may be directly electrically connected between the first bitline BL1 and the ground voltage. For example, the first test cell TC11 may not include an electrical fuse, and the first test transistor TTRI may be directly electrically connected to the first bitline BL1 through a conductor (e.g., through a conductive line). An example connection method between the first test transistor TTR1 and the first bitline BL1 will be described in detail with reference to FIG. 12A below.

The second test cell TC12 may operate based on the voltage level of the second dummy word line DWL2. For example, a gate terminal of the second test transistor TTR2 may be connected to the second dummy word line DWL2.

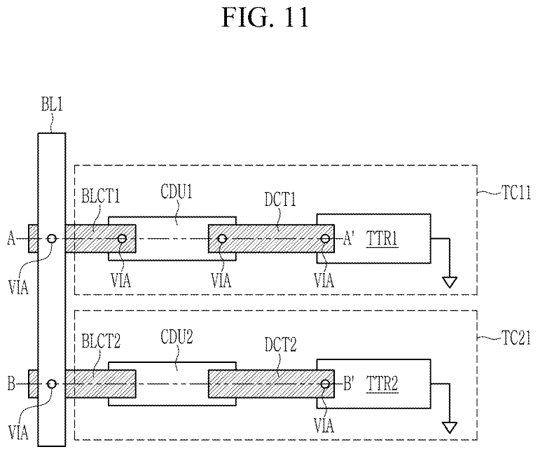

A drain terminal of the second test transistor TTR2 and the first bitline BL1 may not be electrically connected. In other words, the drain terminal of the second test transistor TTR2 and the first bitline BL1 may be electrically open or electrically isolated from each other. According to an embodiment of the present disclosure, the drain terminal of the first test transistor TTR1 and the first bitline BL1 may be shorted in a hard-coding scheme, and the drain terminal of the second test transistor TTR2 and the first bitline BL1 may be opened in a hard-coding scheme. A specific implementation method of the first and second test cells TC11 to TC21 will be described in more detail with reference to FIGS. 11, 12a, and 12b below.

In an embodiment, when the first dummy word line DWLI is activated, the size of current input to the power supply pad PSP may be determined based on the internal resistance of the first bitline select switch 151 and transistor-on-resistance of the first test transistor TTR1.

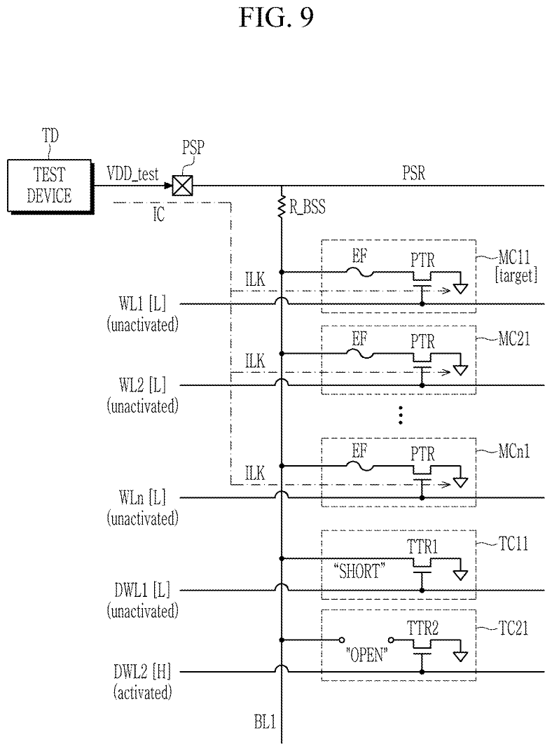

In an embodiment, when the second dummy word line DWL2 is activated, the size of current input to the power supply pad PSP may correspond to the size of leakage current flowing to memory cells connected to the deactivated word line. The size of current input to the power supply pad PSP as the second dummy word line DWL2 is activated will be described in detail with reference to FIG. 9 below.

In an embodiment, the memory device 100 may be implemented such that the first column select signal CSS1 indicates a logic high only when any word line or any dummy word line is activated. However, according to the embodiment of FIG. 4, the operation of the second test transistor TTR2 may not affect the current or voltage of the first bitline BL1. That is, the second dummy word line DWL2 and test cells TC21 to TC2m connected thereto may be provided to change the logic level of the column select signal CSS. In this case, even if the first to nth word lines WL1 to WLn and the first dummy word line DWLI are not activated, a test power source voltage VDD_test may be provided to the first bitline BL1 as the second dummy word line DWL2 is activated.

In an embodiment, the test cell array 120 may include only test cells (e.g., test cells TC11 to TC1m) connected to the first dummy word line DWL1. That is, the test cell array 120 may not include test cells connected to the second dummy word line DWL2. An embodiment in which the test cell array 120 includes only test cells connected to the first dummy word line DWL1 will be described in detail with reference to FIGS. 14 to 16 below.

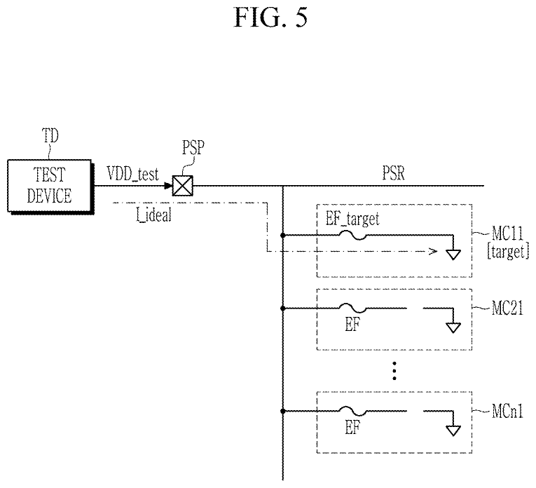

FIG. 5 is a diagram illustrating a method in which the test apparatus of FIG. 1 measures resistance of an electrical fuse included in the memory cell of FIG. 4 according to practical embodiments. Hereinafter, for a more concise description, an embodiment in which the test device TD measures the resistance value of an electrical fuse included in the memory cell MC11 of FIG. 4 (hereinafter referred to as a target electrical fuse EF_target) is representatively described. Accordingly, hereinafter, the memory cell MC11 (e.g., a memory cell being measured) may be referred to as a target memory cell, and a word line connected to the memory cell MC11 may be referred to as a target word line. On the contrary, memory cells other than the target may be referred to as non-target memory cells, and word lines other than the target word line may be referred to as non-target word lines. However, the scope of the present disclosure is not limited to the example above, and resistance values of electrical fuses EF included in other memory cells may be measured in a similar manner.

The test device TD may provide the address ADDR of the target memory cell to the memory device 100. In this case, the memory device 100 may activate a word line and a bitline (e.g., the first word line WL1 and the first bitline BL1) connected to the target memory cell. For example, the row decoder 140 may provide a voltage corresponding to a logic high to the first word line WL1, and the switch controller 160 may provide the first column select signal CSS1 indicating a logic high to the first bitline select switch 141. In this case, word lines other than the word line connected to the target memory cell and other bitlines other than the bitline connected to the target memory cell may be deactivated.

The program transistors PTR connected to an activated word line (i.e., a target word line) may be turned on. For example, the program transistor PTR included in the memory cell MC11 may be turned on. In this case, the target electrical fuse EF_target included in the memory cell MC11 may be electrically connected to the ground voltage.

On the other hand, the program transistors PTR connected to the deactivated word lines (i.e., the non-target word lines) may be turned off. For example, each of the program transistors PTR included in memory cells MC21 to MCnl may be turned off. In this case, the electrical fuse EF included in the memory cells MC21 to MCnl may not be electrically connected to the ground voltage.

The test device TD may provide the test power source voltage VDD_test to the power supply pad PSP. That is, the test device TD may maintain the power supply rail PSR at the test power source voltage VDD_test through the power supply pad PSP.

The first bitline select switch 151 may be turned on in response to the first column select signal CSS1. In this case, the first bitline BL1 may be connected to the power supply rail PSR through the first bitline selection switch 151. Accordingly, the voltage level of the first bitline BL1 may be determined according to the voltage level of the test power source voltage VDD_test.

The test device TD may measure the size of current provided to the power supply pad PSP. That is, the test device TD may measure the size of the current provided by the test device TD to the power supply pad PSP.

The size of current provided from the test device TD to the power supply pad PSP may correspond to the size of current flowing from the first bitline BL1 to the target memory cell. According to the embodiment of FIG. 5, since the current does not flow from the first bitline BL1 to the non-target memory cells, the size of the current flowing from the first bitline BL1 to the target memory cell may be the same as the size of the current I_ideal provided from the test device TD to the power supply pad PSP.

The test device TD may calculate a resistance value of the target electrical fuse EF_target based on the measured current. For example, the test device TD may calculate the resistance value of the target electrical fuse EF_target based on Equation 1 below.

$${R}_{target} = \frac{VDD\_test}{{I}_{ideal}} \qquad ( Equation 1 )$$

(However, Ktarget may represent the resistance value of the target electrical fuse EF_target, VDD_test may represent the voltage level of the test power source voltage VDD_test, and lideat may represent the size of the current measured according to the embodiment of FIG. 5.)

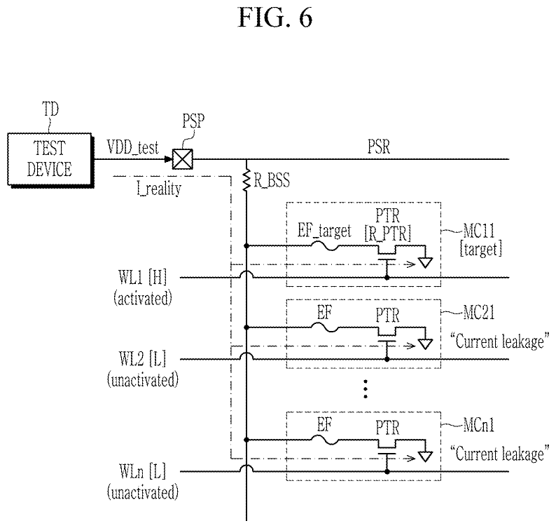

However, when the memory device 100 is implemented in a non-ideal way, a measurement error may be included in the resistance value of the target electrical fuse EF_target calculated by the test device TD based on Equation 1 described above. A measurement error for the calculated resistance value will be described in more detail with reference to FIG. 6 below.

FIG. 6 is a diagram describing a measurement error when the test apparatus of FIG. 1 measures the resistance of an electrical fuse included in the memory cell of FIG. 4. Referring to FIGS. 1 to 6, the memory device 100 may activate a word line and a bitline (e.g., the first word line WL1 and the first bitline BL1) connected to a target memory cell. For example, the row decoder 140 may provide a voltage corresponding to a logic high to the first word line WL1, and the switch controller 160 may provide the first column select signal CSS1 indicating a logic high to the first bitline select switch 151. In this case, word lines other than the word line connected to the target memory cell and bitlines other than the bitline connected to the target memory cell may be deactivated. Hereinafter, differences from the measurement of the resistance value of the ideal memory device described with reference to FIG. 5 will be mainly described.

The first bitline select switch 151 may include an internal resistance component. For example, even if the first bitline select switch 151 is turned on in response to the first column select signal CSS1, the resistance of the first bitline select switch 151 may be greater than ‘0’. That is, even if the first bitline select switch 151 is turned on in response to the first column select signal CSS1, a bitline select switch resistance R_BSS component may be included between the first bitline BL1 and the power supply rail PSR. In this case, unlike the description with reference to FIG. 5, the voltage level of the first bitline BL1 may be different from the voltage level of the power supply rail PSR.

In an embodiment, a size of the bitline select switch resistance R_BSS may be determined based on a transistor-on-resistance of a transistor included in the first bitline select switch 151. However, the scope of the present disclosure is not limited thereto.

The program transistor PTR included in the target memory cell may include an internal resistance component. For example, even if the program transistor PTR included in the target memory cell is turned on, the resistance of the program transistor PTR may be greater than ‘O’. In this case, unlike the description with reference to FIG. 5, a program transistor-on-resistance R_PTR component may be further included between the target electrical fuse EF_target and the ground voltage.

Leakage current flowing from the first bitline BL1 to non-target memory cells may occur. For example, even if the program transistor PTR included in the non-target memory cell is turned off, a leakage current may occur in a direction from a drain terminal to a source terminal of the program transistor PTR included in the non-target memory cell. In this case, the size of a current I_reality measured by the test device TD may be different from the size of the current flowing through the target electrical fuse EF_target.

Accordingly, a measurement error may occur in the resistance value of the target electrical fuse EF_target calculated by the test device TD based on the current I_reality. Hereinafter, an operation of the test system TS for compensating for this measurement error will be described in detail.

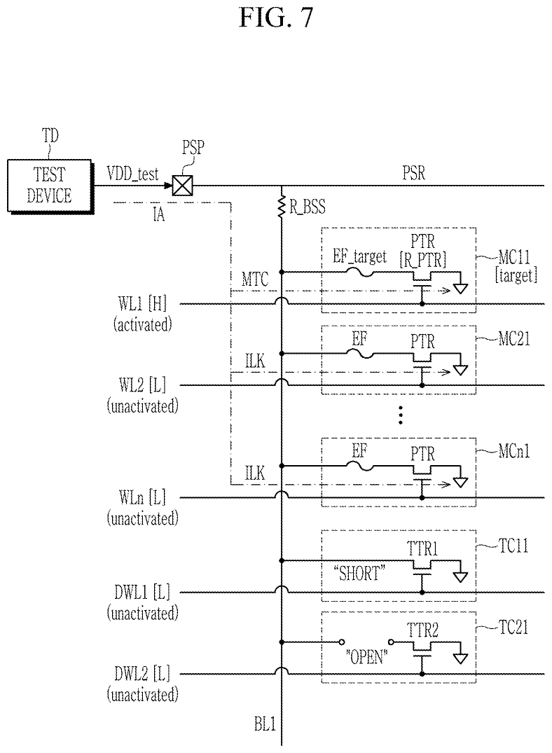

FIG. 7 is a diagram illustrating the operation of a test system according to an embodiment of the present disclosure. Hereinafter, an operation of the test system TS in a case where the memory cell MC11 is a target memory cell will be representatively described similarly to that previously described with reference to FIGS. 5 and 6.

Referring to FIGS. 1 to 4 and 7, the test device TD may provide the address ADDR of the target memory cell to the memory device 100. For example, the test device TD may provide the address of the memory cell MC11 to the memory device 100. In this case, the memory device 100 may activate the first bitline BL1 and the first word line WL1. For example, the memory device 100 may turn on the first bitline select switch 151, and may provide a voltage corresponding to logic high to the first word line WL1.

Hereinafter, for a more concise description, in response to activation of the first bitline BL1 and the first word line WL1, the current flowing from the first bitline BL1 to the target memory cell will be referred to as measurement target current MTC, and a current flowing from the first bitline BL1 to memory cells (e.g., non-target memory cells) connected to deactivated word lines will be referred to as leakage current ILK. However, the scope of the present disclosure is not limited to these terms.

The test device TD may measure the current (hereinafter, referred to as first current IA) provided to the power supply pad PSP in response to activation of the first bitline BL1 and the first word line WL1. In this case, the size of the first current IA may correspond to the sum of the size of the measurement target current MTC and the size of the leakage current ILK. Though a single value is given for the leakage current ILK in the various embodiments and discussions herein, as can be seen from the figures, a plurality of leakage currents ILK may occur for different unactivated wordlines, which added together result in the leakage current being discussed in the various embodiments when only one current is mentioned.

The measurement target current MTC may refer to the current flowing to the target memory cell through the power supply pad PSP and the first bitline selection switch 151. In this case, the size of the measurement target current MTC may vary based on the resistance value of the target electrical fuse EF_target, as well as the bitline select switch resistance R_BSS and the program transistor-on-resistance R_PTR.

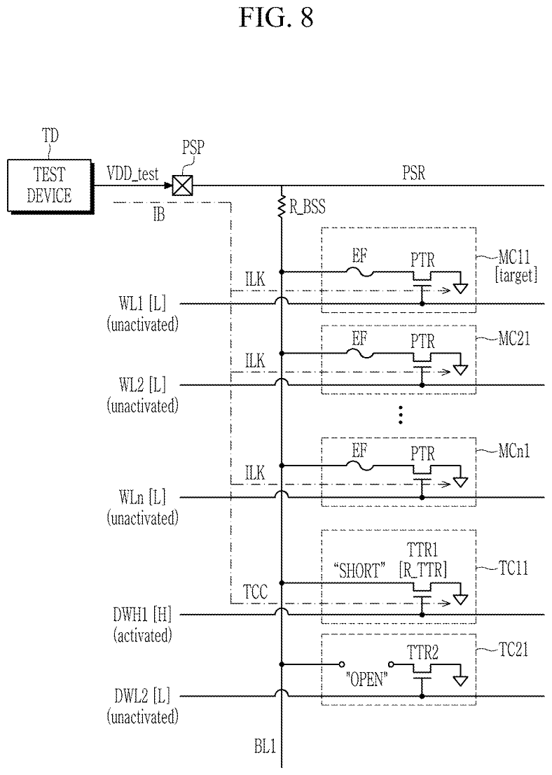

Therefore, when the resistance value of the target electrical fuse EF_target is calculated based on the size of the first current IA, similarly to that described above with reference to FIG. 6, the calculated resistance value may include the bitline select switch resistance R_BSS and the program transistor-on-resistance R_PTR, and may be affected by the leakage current ILK. Hereinafter, a specific method for compensating for this error will be described with reference to FIGS. 8 to 10.

FIG. 8 is a diagram illustrating the operation of a test system according to an embodiment of the present disclosure. Referring to FIGS. 1 to 4 and 7 to 8, the test device TD may provide the address ADDR of the first test cell TC11 to the memory device 100. In this case, the memory device 100 may activate the first bitline BL1 and the first dummy word line DWL1. For example, the row decoder 140 may provide a voltage corresponding to logic high to the first dummy word line DWL1, and the switch controller 160 may turn on the first bitline select switch

Hereinafter, for a more concise description, in response to the activation of the first bitline BL1 and the first dummy word line DWL1, the current flowing from the first bitline BL1 to the first test cell TC11 will be referred to as test cell current TCC.

In response to activation of the first bitline BL1 and the first dummy word line DWL1, the test device TD may measure a current (hereinafter, referred to as a second current IB) provided to the power supply pad PSP. In this case, the size of the second current IB may correspond to the sum of the size of the test cell current TCC and the size of the leakage current ILK.

The test cell current TCC may refer to a current flowing to the test cell TC11 through the power supply pad PSP and the first bitline select switch 151. In this case, the size of the test cell current TCC will vary based on the components of the bitline select switch resistance R_BSS and the test transistor-on-resistance R_TTR.

A size of the test transistor TTR1 may correspond to a size of the program transistor PTR. For example, the size of the test transistor TTR1 may be the same as that of the program transistor PTR. In this case, the size of the test transistor-on-resistance R_TTR may correspond to the size of the program transistor-on-resistance R_PTR.

FIG. 9 is a diagram illustrating the operation of a test system according to an embodiment of the present disclosure. Referring to FIGS. 1 to 4 and 7 to 9, the test device TD may provide the address ADDR of the second test cell TC12 to the memory device 100. In this case, the memory device 100 may activate the first bitline BL1 and the second dummy word line DWL2. For example, the row decoder 140 may provide a voltage corresponding to logic high to the second dummy word line DWL2, and the switch controller 160 may turn on the first bitline select switch 141.

The second test transistor TTR2 connected to the second dummy word line DWL2 may not be electrically connected to the first bitline BL1. Accordingly, even when a voltage corresponding to logic high is applied to the second dummy word line DWL2, the size of current flowing from the first bitline BL1 to the second test cell TC21 may be ‘0’.

In response to activation of the first bitline BL1 and the second dummy word line DWL2, the test device TD may measure a current (hereinafter, referred to as a third current IC) provided to the power supply pad PSP. In this case, the size of the third current IC may correspond to the sum of the leakage currents ILK. That is, the third current IC may correspond to the sum of currents flowing in memory cells (i.e., non-target memory cells) connected to the deactivated word lines.

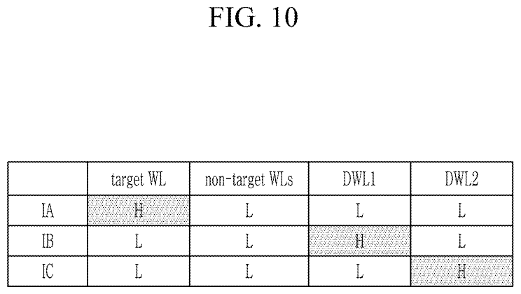

FIG. 10 is a diagram illustrating the operation of a test system according to an embodiment of the present disclosure. Referring to FIGS. 1 to 4 and 7 to 10, when the first current IA is measured, a voltage corresponding to logic high may be provided to the target word line (e.g., the first word line WL1). On the contrary, voltages corresponding to logic lows may be provided to non-target word lines (e.g., the second to n-th word lines WL2 to WLn) and the first to second dummy word lines DWL1 to DWL2.

When the second current IB is measured, a voltage corresponding to logic high may be provided to the first dummy word line DWL1. On the contrary, a voltage corresponding to logic low may be provided to all word lines (i.e., the first to n-th word lines WLI to WLn) connected to the memory cell array 110 and to the second dummy word line DWL2.

When the third current IC is measured, a voltage corresponding to logic high may be provided to the second dummy word line DWL2. On the contrary, a voltage corresponding to logic low may be provided to all word lines (i.e., the first to n-th word lines WLI to WLn) connected to the memory cell array 110 and to the first dummy word line DWL1.

The test device TD may calculate the resistance value of the target electrical fuse EF_target based on the first current IA, the second current IB, and the third current IC. For example, the test device TD may perform a compensation calculation operation on the first current IA based on the second current IB and the third current IC to calculate the resistance value of the target electrical fuse EF_target.

A difference between the first current IA and the third current IC may correspond to the measurement target current MTC. Therefore, the measurement target current MTC may be calculated based on Equation 2 below.

$${I}_{MTC} = {I}_{A} - {I}_{C} = \frac{VDD\_test}{{R}_{target} + {R}_{BSS} + {R}_{PTR}} \qquad ( Equation 2 )$$

Here, IxTe may represent the size of the measurement target current MTC, IA may represent the size of the first current IA, Ic may represent the size of the third current IC, VDD_test may represent a voltage level of the test power source voltage VDD_test, Rtarget may represent a resistance value of the target electrical fuse EF_target, Ress may represent the size of the bitline select switch resistance R_BSS, and RPTR may represent the size of the program transistor-on-resistance R_PTR.

Similarly, the difference between the second current IB and the third current IC may correspond to the test cell current TCC. Therefore, the test cell current TCC may be calculated based on Equation 3 below.

$${I}_{TCC} = {I}_{B} - {I}_{C} = \frac{VDD\_test}{{R}_{BSS} + {R}_{TTR}} \qquad ( Equation 3 )$$

Here, Ircc represents the size of the test cell current TCC, Is represents the size of the second current IB, Ic represents the size of the third current IC, VDD_test represents the voltage level of the test power source voltage VDD_test, Ress represents the size of the bitline select switch resistance R_BSS, and RTTR represents the size of the test transistor-on-resistance R_TTR.

The size of the first test transistor TTR1 may be the same as that of the program transistor PTR. In this case, the size of the test transistor-on-resistance R_TTR may be the same as the size of the program transistor-on-resistance R_PTR. That is, RPTR in Equation 2 described above may have the same size as that in Equation 3.

Accordingly, the test device TD may calculate the resistance value of the target electrical fuse EF_target based on Equations 2 and 3 described above. For example, the test device TD may calculate the resistance value of the target electrical fuse EF_target based on Equation 4 below.

$${R}_{target} = \frac{VDD\_test}{{I}_{A} - {I}_{C}} - \frac{VDD\_test}{{I}_{B} - {I}_{C}} \qquad ( Equation 4 )$$

That is, according to Equation 4, an error in the resistance value of the target electrical fuse EF_target caused by the bitline select switch resistance R_BSS, the program transistor-on-resistance R_PTR, and the leakage current ILK may be compensated. Accordingly, according to embodiments of the present disclosure, since the resistance value of the target electrical fuse EF_target may be more accurately measured, a test operation for the memory device 100 may be more accurately performed.

FIG. 11 is a schematic view illustrating a first bitline and test cells of FIG. 4 implemented according to an embodiment. Referring to FIGS. 1 to 4 and 11, the first bitline BL1 may be connected to a first bitline contact BLCT1 and a second bitline contact BLCT2 through a via VIA.

The test cell TC11 may include the first test transistor TTR1. A drain terminal of the first test transistor TTR1 may be connected to a first drain contact DCT1 through the via VIA. A source terminal of the first test transistor TTR1 may be connected to the ground voltage.

The test cell TC21 may include the second test transistor TTR2. A drain terminal of the second test transistor TTR2 may be connected to a second drain contact DCT2 through the via VIA. A source terminal of the second test transistor TTR2 may be connected to the ground voltage.

A first conductor CDU1 may be connected to the first bitline contact BLCTI and the first drain contact DCT1 through the via VIA. That is, the drain terminals of the first bitline BL1 and the first test transistor TTR1 may be electrically connected to each other through the first bitline contact BLCT1, the first conductor CDU1, and the first drain contact DCT1. A connection relationship between the first bitline BL1 and the drain terminal of the first test transistor TTR1 will be described in detail with reference to FIG. 12A below.

On the contrary, the second conductor CDU2 may not be electrically connected to the second bitline contact BLCT2 and the second drain contact DCT2. That is, drain terminals of the first bitline BL1 and the second test transistor TTR2 may not be electrically connected to each other. A connection relationship between the first bitline BL1 and the drain terminal of the second test transistor TTR2 will be described in detail with reference to FIG. 12B below.

In an embodiment, the first conductor CDU1 and the second conductor CDU2 may be disposed at positions corresponding to the plurality of electrical fuses EF included in the memory cell array 110. For example, the relative position of the first conductor CDU1 with respect to the first bitline BL1 and the first test transistor TTR1 may correspond to the relative position of the electrical fuse EF included in the memory cell MC11 with respect to the first bitline BL1 and the program transistor PTR. In this case, the production process of the memory device 100 may be more simplified. However, the scope of the present disclosure is not limited to specific implementation methods of the first conductor CDU1 and the second conductor CDU2.

FIGS. 12A and 12B are cross-sectional views illustrating a connection relationship between the first bitline and test cells of FIG. 11 in more detail, implemented according to an embodiment. Hereinafter, a cross-sectional view taken in the direction of the substrate of the memory device 100 taken along the A-A′ line of FIG. 11 will be described with reference to FIG. 12A, and a cross-sectional view cut in the direction of the substrate of the memory device 100 taken along the B-B′ line of FIG. 11 with reference to FIG. 12B. will be described.

Referring to FIG. 12A, a first metal layer MLa, a second metal layer MLb, and a third metal layer MLc may be stacked on a substrate SUB of the memory device 100. An interlayer insulating layer ISL may be formed between the first metal layer MLa, the second metal layer MLb, and the third metal layer MLc.

In an embodiment, the interlayer insulating layer ISL may include or be formed of an insulating material such as silicon oxide or silicon nitride.

In an embodiment, the first metal layer MLa, the second metal layer MLb, and the third metal layer MLc may include or be formed of a metal, a metal compound, or a conductive material such as polysilicon.

The first metal layer MLa may form the first conductor CDU1. The second metal layer MLb may form the first bitline contact BLCTI and the first drain contact DCT1. The third metal layer MLc may form the first bitline BL1.

The first metal layer MLa and the second metal layer MLb may be connected through a first via VIAa. For example, the first metal layer MLa may be electrically connected to a region forming the first bitline contact BLCT1 of the second metal layer MLb through the first via VIAa, and may be electrically connected to a region forming the first drain contact DCT1 of the second metal layer MLb.

The second metal layer MLb may be connected to an active region ACT on the substrate SUB through a second via VIAb. More specifically, the region forming the first drain contact DCT1 of the second metal layer MLb may be connected to the active region ACT through the second via VIAb. The active region ACT may form a drain terminal of the first test transistor TTR1.

The second metal layer MLb and the third metal layer MLc may be connected through a third via VIAc. More specifically, a region forming the first bitline contact BLCTI of the second metal layer MLb may be connected to the third metal layer MLc through the third via VIAc.

According to the embodiment of FIG. 12A, the first bitline BL1 may be electrically connected to the drain terminal of the first test transistor TTR1 (e.g., it may be directly electrically connected to the drain terminal).

For a more concise description, FIG. 12A illustrates an embodiment in which the first bitline contact BLCT1 and the first drain contact DCT1 are formed on the same metal layer, and the first conductor CDU1 is disposed on a metal layer adjacent to the substrate SUB. However, the scope of the present disclosure is not limited to a specific method of forming the first bitline contact BLCT1, the first conductor CDU1, the first drain contact DCT1, and the first bitline BL1.

Referring to FIG. 12B, the first metal layer MLa, the second metal layer MLb, and the third metal layer MLc may be stacked on the substrate of the memory device 100. The interlayer insulating layer ISL may be formed between the first metal layer MLa, the second metal layer MLb, and the third metal layer MLc.

The first metal layer MLa may form the second conductor CDU2. The second metal layer MLb may form the second bitline contact BLCT2 and the second drain contact DCT2. The third metal layer MLc may form the first bitline BL1.

The second metal layer MLb may be connected to the active region ACT on the substrate SUB through the second via VIAb. The second metal layer MLb and the third metal layer MLc may be connected through the third via VIAc. Since the second via VIAb and the third via VIAc are similar to those described above with reference to FIG. 12A, a detailed description thereof will be omitted.

The first metal layer MLa and the second metal layer MLb may not be electrically connected. For example, a via may not be formed between the first metal layer MLa and the second metal layer MLb. That is, unlike the description with reference to FIG. 12A, the first metal layer MLa and the second metal layer MLb may be separated and electrically isolated by the interlayer insulating layer ISL.

Accordingly, according to the embodiment of FIG. 12B, the first bitline BL1 may not be electrically connected to the drain terminal of the second test transistor TTR2. In this case, even if the voltage level provided to the gate terminal of the second test transistor TTR2 is different, current does not flow from the first bitline BL1 to the drain terminal of the second test transistor TTR2.

In an embodiment, the first conductor CDU1 and the second conductor CDU2 may be formed at the same layer as the electrical fuse EF included in the memory cell array 110. For example, the electrical fuse EF may be formed at the first metal layer MLa. However, the scope of the present disclosure is not limited to the method in which the first conductor CDU1, the second conductor CDU2, and the electrical fuse EF are formed. For example, unlike those shown in FIGS. 12A and 12B, the first conductor CDU1, the second conductor CDU2, and the electrical fuse EF may be formed on the substrate SUB.

For a more concise description, an embodiment in which no via is formed between the first metal layer MLa and the second metal layer MLb is representatively illustrated in FIG. 12B, but the scope of the present disclosure is not limited thereto. For example, a via may be formed between the second conductor CDU2 and the first bitline contact BLCTI, but a via may not be formed between the second conductor CDU2 and the first drain contact DCT1. Alternatively, a via may not be formed between the second conductor CDU2 and the first bitline contact BLCT1, but a via may be formed between the second conductor CDU2 and the first drain contact DCT1. For another example, the second test cell TC12 may not include the second conductor CDU2. Even in these cases, the drain terminals of the first bitline BL1 and the second test transistor TTR2 may not be electrically connected. That is, the scope of the present disclosure is not limited to a specific method in which the drain terminals of the first bitline BL1 and the second test transistor TTR2 are electrically separated.

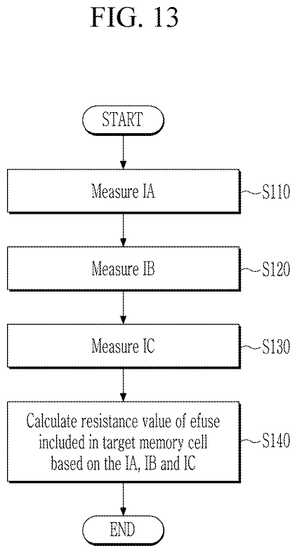

FIG. 13 is a flowchart illustrating the operation of the test apparatus of FIG. 1. Referring to FIGS. 1 to 12, in step S110, the test device TD may measure the first current IA. For example, similarly to that described with reference to FIG. 7, the test device TD may provide the address ADDR of the target memory cell to the memory device 100 and measure the size of the current provided to the power supply pad PSP.

In step S120, the test device TD may measure the second current IB. For example, similarly to the description with reference to FIG. 8, the test device TD may provide the address ADDR for the first test cell TC11 to the memory device 100, and measure the size of the current provided to the power supply pad PSP.

In step S130, the test device TD may measure the third current IC. For example, similarly to the description with reference to FIG. 8, the test device TD may provide the address ADDR for the second test cell TC21 to the memory device 100, and measure the size of the current provided to the power supply pad PSP.

In step S140, the test device TD may calculate a resistance value of an electrical fuse included in the target memory cell (i.e., the target electrical fuse EF_target) based on the first to third currents IA to IC. For example, the test device TD may calculate the resistance value of the target electrical fuse EF_target based on Equation 4 described above.

In an embodiment, the order of steps S110 to S130 described above may be different. For example, unlike that shown in FIG. 13, step S130 may be performed before step S110 and/or step S120, or step S120 may be performed before step S110. That is, the scope of the present disclosure will not be limited to the order in which steps S110 to S130 are performed.

FIG. 14 is a diagram illustrating some configurations of FIG. 2 implemented according to an embodiment in more detail. Referring to FIGS. 1, 2, and 14, the memory cell array 110 may include a plurality of memory cells MC. The plurality of memory cells MC may be connected to the first to m-th bitlines BLm. The first to m-th bitlines BLm may be connected to the bitline selector 150. Since configurations and functions of the memory cell array 110 and the bitline selector 150 are similar to those previously described with reference to FIG. 3, a detailed description thereof will be omitted.

The test cell array 120 may include a plurality of test cells TC. Each of the plurality of test cells TC may be connected to the first dummy word line DWL1. For example, the test cell array 120 may include the test cells TC11 to TCIm. That is, unlike the description with reference to FIG. 3, each test cell TC included in the test cell array 120 may be connected to one dummy word line.

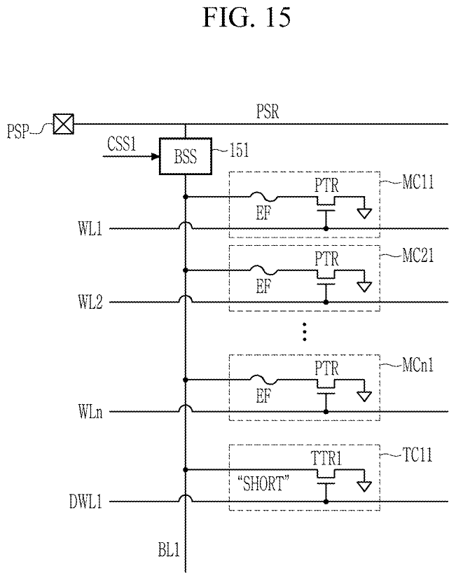

FIG. 15 is a diagram illustrating some configurations of FIG. 14 in more detail. Referring to FIGS. 1, 2, 14, and 15, the memory cells MC11 to MCnl and the test cell TC11 may be connected to the first bitline BL1. Since configurations and operations of the memory cells MC11 to MCnl and the test cell TC11 are similar to those described with reference to FIG. 4, a detailed description thereof will be omitted.

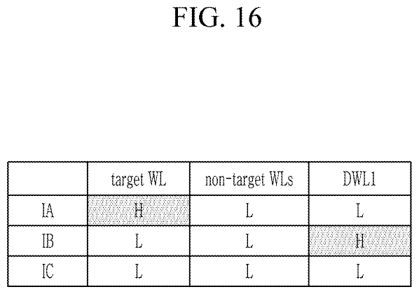

FIG. 16 is a diagram illustrating first to third current measurement methods when a memory device is implemented according to the embodiment of FIG. 14.

Referring to FIGS. 1, 2, and 14 to 16, when the first current IA is measured, a voltage corresponding to a logic high may be provided to a target word line (e.g., the first word line WL1). On the other hand, a voltage corresponding to logic low may be applied to non-target word lines (e.g., the second through n-th word lines WL2 to WLn) and the first dummy word line DWL1.

When the second current IB is measured, a voltage corresponding to logic high may be provided to the first dummy word line DWL1. On the other hand, a voltage corresponding to logic low may be applied to all word lines (i.e., the first to n-th word lines WLI to WLn) connected to the memory cell array 110.

When the third current IC is measured, a voltage corresponding to logic low may be applied to all word lines connected to the memory cell array 110 and to the first dummy word line DWL1. That is, when the third current IC is measured, only the first bitline BL1 may be activated.

The third current IC may correspond to leakage current occurring due to the activation of the first bitline BL1.

Since a method for the test device TD to calculate the resistance value of the electrical fuse included in the target memory cell based on the first to third currents IA to IC is similar to that described above with reference to FIGS. 1 to 10, a detailed description thereof will be omitted.

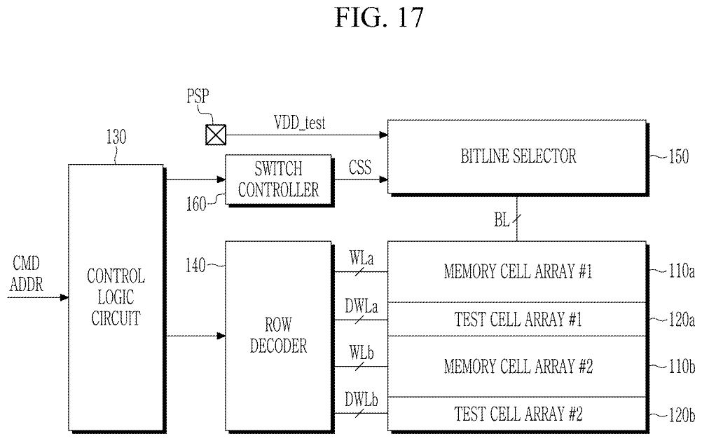

FIG. 17 is a block diagram illustrating the memory device of FIG. 1 according to an embodiment. Referring to FIGS. 1, 2 and 17, the memory device 100 may include the control logic circuit 130, the row decoder 140, the bitline selector 150, the switch controller 160, and the power supply pad PSP. Since configurations and functions of the control logic circuit 130, the row decoder 140, the bitline selector 150, the switch controller 160, and the power supply pad PSP are similar to those described above with reference to FIG. 2, a detailed description thereof will be omitted.

The memory device 100 may include a plurality of memory cell arrays. For example, the memory device 100 may include a first memory cell array 110a and a second memory cell array 110b.

The memory device 100 may include a plurality of test cell arrays. For example, the memory device 100 may include a first test cell array 120a and a second test cell array 120b.

Hereinafter, for more concise description, an embodiment in which the memory device 100 includes two memory cell arrays and two test cell arrays will be described. However, the scope of the present disclosure is not limited to the number of memory cell arrays and test cell arrays included in the memory device 100.

The first memory cell array 110a may be connected to first word lines WLa. The second memory cell array 110b may be connected to second word lines WLb. That is, the first memory cell array 110a and the second memory cell array 110b may be connected to different word lines.

The first test cell array 120a may be connected to first dummy word lines DWLa. The second test cell array 120b may be connected to second dummy word lines DWLb. That is, the first test cell array 120a and the second test cell array 120b may be connected to different dummy word lines.

When the target memory cell is included in the first memory cell array 110a, the test device TD may measure the second to third currents IB to IC using the first test cell array 120a. For example, the test device TD may sequentially activate the first dummy word lines DWLa to measure the second and third currents IB to IC.

Similarly, when the target memory cell is included in the second memory cell array 110b, the test device TD may measure the second to third currents IB to IC using the second test cell array 120b. For example, the test device TD may sequentially activate the second dummy word lines DWLb to measure the second and third currents IB to IC.

The first test cell array 120a may be disposed adjacent to the first memory cell array 110a. The second test cell array 120b may be disposed adjacent to the second memory cell array 110b. In this case, the distance between the target memory cell and the test cell may be minimized. Therefore, according to the embodiment of FIG. 17, an error in the resistance value of the target electrical fuse calculated by the test device TD, which may occur due to parasitic resistance of the bitline between the target memory cell and the test cell, can be minimized.

FIG. 18 is a block diagram illustrating a memory system including the memory device of FIG. 1. Referring to FIGS. 1 to 18, a memory system MS may include the memory device 100 and a memory controller CTR.

The memory controller CTR may be one of various types of processors, such as a central processing unit (CPU) and a graphic processing unit (GPU).

The memory device 100 may include the plurality of memory cells MC. The memory controller CTR may write data DATA to the plurality of memory cells MC or read data DATA from the plurality of memory cells MC. For example, the memory controller CTR may control the memory device 100 by transmitting the command CMD and/or the address ADDR to the memory device 100.

The memory controller CTR may provide a driving power source voltage VDD_op to the memory device 100. The memory device 100 may perform an operation corresponding to the received command CMD and/or address ADDR based on the driving power source voltage VDD_op. For example, the memory controller CTR may perform a program operation on the memory device 100 based on the driving power source voltage VDD_op.

In an embodiment, when a program operation for the memory device 100 is performed, the driving power source voltage VDD_op may have a higher voltage level than the test power source voltage VDD_test.

In an embodiment, when the memory controller CTR performs a program operation on the memory device 100, the driving power source voltage VDD_op may have a voltage level of about 1.5V to 1.8V. However, the scope of the present disclosure is not limited to the voltage level of the driving power source voltage VDD_op. For example, when the memory controller CTR performs a program operation on the memory device 100, the voltage level of the driving power source voltage VDD_op may be about 5V.

In an embodiment, the driving power source voltage VDD_op and the test power source voltage VDD_test may be provided to the memory device 100 through the same pad. That is, the memory device 100 may receive the test power source voltage VDD_test from the test device TD or the driving power source voltage VDD_op from the memory controller CTR through one power supply pad PSP.

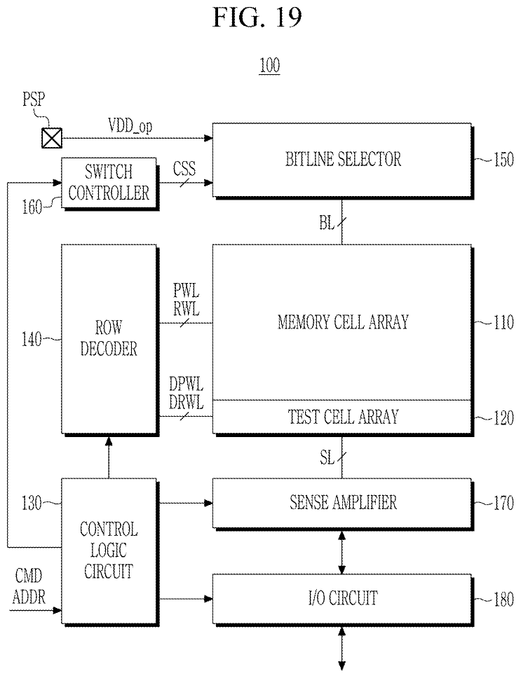

FIG. 19 is a block diagram illustrating the memory device of FIG. 18 in more detail. Referring to FIGS. 1 to 19, the memory device 100 may include the memory cell array 110, the test cell array 120, the control logic circuit 130, the row decoder 140, the bitline selector 150, the switch controller 160, a sense amplifier 170, an input/output circuit 180, and the power supply pad PSP. Detailed descriptions of the above-described memory cell array 110, the test cell array 120, the control logic circuit 130, the row decoder 140, the bitline selector 150, and the switch controller 160 are omitted.

The memory cell array 110 may include a plurality of memory cells. The plurality of memory cells may be connected to a plurality of program word lines PWL and a plurality of read word lines RWL extending in a row direction. The plurality of memory cells may be connected to the plurality of bitlines BL and a plurality of sensing lines SL extending in a column direction.

In an embodiment, the plurality of program word lines PWL may correspond to the word lines WL previously described with reference to FIGS. 1 to 17. However, the scope of the present disclosure is not limited thereto.

The test cell array 120 may include a plurality of test cells. The plurality of test cells may be connected to a plurality of dummy program word lines DPWL and a plurality of dummy read word lines DRWL extending in a row direction. The plurality of test cells may be connected to the plurality of bitlines BL and the plurality of sensing lines SL extending in a column direction.

In an embodiment, the plurality of dummy program word lines DPWL may correspond to the dummy word lines DWL previously described with reference to FIGS. 1 to 17. However, the scope of the present disclosure is not limited thereto.

Since a detailed implementation method of the memory cell array 110 and the test cell array 120 connected to the bitlines BL has been described with reference to FIG. 3, a detailed description thereof will be omitted.

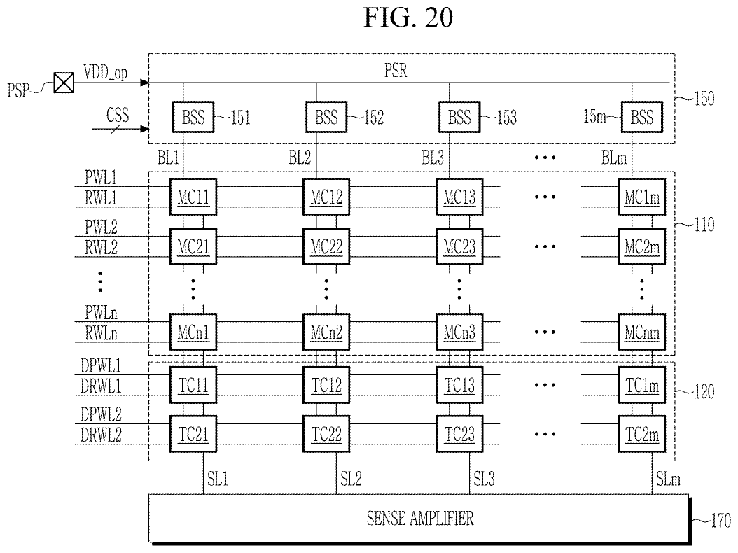

The memory cell array 110 and the test cell array 120 may be connected to the same sensing lines SL. For example, the memory cell array 110 and the test cell array 120 may share sensing lines SL. A detailed implementation method of the memory cell array 110 and the test cell array 120 connected to the sensing lines SL will be described below with reference to FIG. 20.

The control logic circuit 130 may control overall operations of the memory device 100 based on the command CMD and address ADDR provided from the memory controller CTR. For example, the control logic circuit 130 may control the operation of the row decoder 140, the switch controller 160, the sense amplifier 170, and the input/output circuit 180 based on the command CMD and the address ADDR.

The row decoder 140 may control the plurality of program word lines PWL, the plurality of read word lines RWL, the plurality of dummy program word lines DPWL, and the plurality of dummy read word lines DRWL based on the address ADDR. For example, the row decoder 140 may activate one of the plurality of program word lines PWL, the plurality of read word lines RWL, the plurality of dummy program word lines DPWL, and the plurality of dummy read word lines DRWL based on the address ADDR.

The bitline selector 150 may be connected to the plurality of bitlines BL. The bitline selector 150 may receive the driving power source voltage VDD_op from the memory controller

CTR through the power supply pad PSP.

The sense amplifier 170 may be connected to the memory cell array 110 through the plurality of sensing lines SL. The sense amplifier 170 may sense voltage level changes of the plurality of sensing lines SL and temporarily store data of the memory cell array 110. For example, the sense amplifier 170 may store data of memory cells connected to an activated word line.

The input/output circuit 180 may receive data from the memory controller CTR or transmit data to the memory controller CTR. For example, the input/output circuit 180 may write received data into the memory cell array 110 or output data stored in the sense amplifier 170 to the memory controller CTR.

FIG. 20 is a diagram illustrating some configurations of FIG. 19 in more detail. Referring to FIGS. 1 to 3, the memory cell array 110 may include the plurality of memory cells MC. The test cell array 120 may include the plurality of test cells TC.

Since configurations of the power supply pad PSP and the bitline selector 150 are similar to those described above with reference to FIG. 3, a detailed description thereof will be omitted.

The plurality of memory cells MC may be connected to first to n-th program word lines PWL1 to PWLn. The plurality of memory cells MC may be connected to the first to n-th read word lines RWL1 to RWLn. The plurality of memory cells MC may be connected to the first to m-th bitlines BLm. The plurality of memory cells MC may be connected to first to m-th sensing lines SLI to SLm. Hereinafter, for more concise description, memory cell connected to a (i)th program word line, a (i)th read word line, a (j)th bitline, and a (j)th sensing line are referred to as memory cell MCij.

The plurality of test cells TC may be connected to first to second dummy program word lines DPWLI to DPWLn. The plurality of test cells TC may be connected to first to second dummy read word lines DRWLI to DRWL2.

The plurality of test cells TC may be connected to the first to m-th bitlines BLm. The plurality of test cells TC may be connected to the first to m-th sensing lines SLI to SLm. Hereinafter, for a more concise description, the test cell connected to the (i)th program word line, the (i)th read word line, the (j)th bitline, and the (j)th sensing line are referred to as test cell TCij.

Hereinafter, for a more concise description, an embodiment in which the test cell array 120 is connected to the first to second dummy program word lines DPWLI to DPWLn and to the first to second dummy read word lines DRWLI to DRWL2 will be representatively described. However, the scope of the present disclosure is not limited thereto. For example, unlike shown in FIG. 20, the test cell array 120 may not be connected to the first to second dummy read word lines DRWLI to DRWL2.

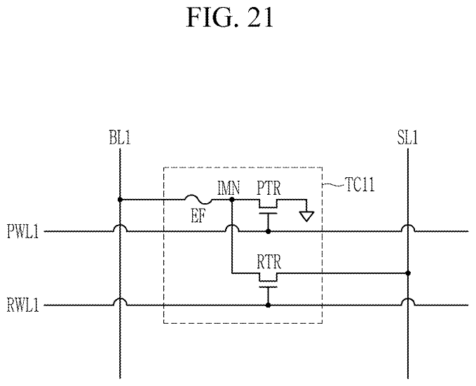

FIG. 21 is a circuit diagram illustrating a configuration of one of the memory cells of FIG. 20 in more detail. Hereinafter, the configuration of the memory cell MC11 of FIG. 20 will be representatively described with reference to FIG. 21. However, the scope of the present disclosure is not limited thereto, and each of the plurality of memory cells MC may be configured similarly to the memory cell MC11.

Referring to FIGS. 1 to 21, the memory cell MC11 may include the electrical fuse EF, the program transistor PTR, and a read transistor RTR. Since functions and operations of the electrical fuse EF and the program transistor PTR are similar to those described above with reference to FIGS. 1 to 17, a detailed description will be omitted.

The memory cell MC11 may be connected to the first bitline BL1, the first sensing line SL1, the first program word line PWL1, and the first read word line RWL1.

The electrical fuse EF may be connected between the first bitline BL1 and an intermediate node IMN. The program transistor PTR may be connected between the intermediate node IMN and the ground voltage. The read transistor RTR may be connected between the intermediate node IMN and the first sensing line SL1.

The program transistor PTR may operate in response to the voltage level of the first program word line PWL1. The read transistor RTR may operate in response to the voltage level of the first read word line RWL1.

When the electrical fuse EF is blown, current may not flow from the first bitline BL1 to the first sensing line SLI even if a voltage corresponding to logic high is applied to the first read word line RWL1. In this case, the sense amplifier 170 may determine that the memory cell MC11 stores data corresponding to ‘l’. However, the scope of the present disclosure is not limited thereto.

When the electrical fuse EF is not blown, the read transistor RTR may be turned on in response to a voltage corresponding to a logic high being applied to the first read word line RWL1. Accordingly, current may flow from the first bitline BL1 to the first sensing line SL1. In this case, the sense amplifier 170 may determine that the memory cell MC11 stores data corresponding to ‘0’. However, the scope of the present disclosure is not limited thereto.

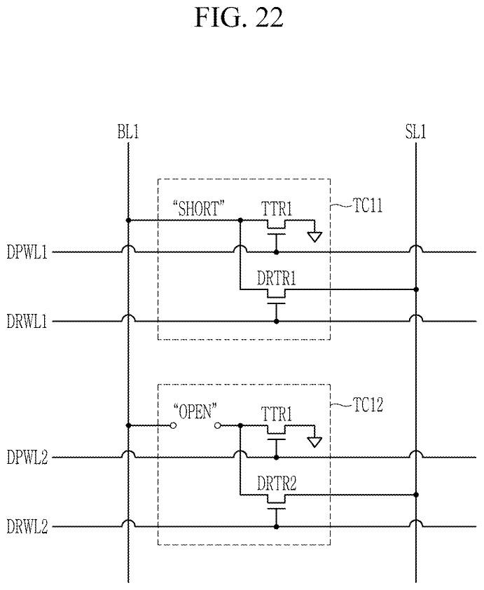

FIG. 22 is a circuit diagram illustrating the configuration of the test cell of FIG. 20 in more detail. Hereinafter, the configuration of the test cells TC11 and TC21 of FIG. 20 will be representatively described with reference to FIG. 22. However, the scope of the present disclosure is not limited thereto, and each of the plurality of test cells TC may be configured similarly to one of the test cells TC11 and TC21.

Referring to FIGS. 1 to 22, the memory cell MC11 may include the electrical fuse EF, the program transistor PTR, and the read transistor RTR. Since functions and operations of the electrical fuse EF and the program transistor PTR are similar to those described above with reference to FIGS. 1 to 17, a detailed description will be omitted.

The test cell TC11 may include the first test transistor TTR1 and a first dummy read transistor DRTR1.

The first test transistor TTR1 may be connected between the first bitline BL1 and the ground voltage. A gate terminal of the first test transistor TTR1 may be connected to the first dummy program word line DPWL1.

The first dummy read transistor DRTR1 may be connected between the first bitline BL1 and the first sensing line SL1. A gate terminal of the first dummy read transistor DRTR1 may be connected to the first dummy read word line DRWL1.

The test cell TC12 may include the second test transistor TTR2 and a second dummy read transistor DRTR2.

A gate terminal of the second test transistor TTR2 may be connected to a second dummy program word line DPWL2. A drain terminal of the second test transistor TTR2 and the first bitline BL1 may not be electrically connected. Since the specific method in which the drain terminal of the second test transistor TTR2 and the first bitline BL1 are not electrically connected has been described with reference to FIGS. 11, 12A, and 12B, a detailed description thereof will be omitted.

The second dummy read transistor DRTR2 may be connected between the drain terminal of the second test transistor TTR2 and the first sensing line SL1. A gate terminal of the second dummy read transistor DRTR2 may be connected to the second dummy read word line DRWL2.

In an embodiment, the test cells TC11 and TC21 may not store data. That is, each of the test cells TC11 and TC21 may not include an electrical fuse.

For a more concise description, an embodiment in which the test cell TC11 includes the first dummy read transistor DRTRI and the test cell TC21 include the second dummy read transistor DRTR2 is representatively described in FIG. 22. However, the scope of the present disclosure is not limited thereto. For example, the test cell TC11 may not include the first dummy read transistor DRTR1, and the test cell TC21 may not include the second dummy read transistor DRTR2. That is, the test cell TC11 and the test cell TC21 may be implemented in the method previously described with reference to FIG. 4.

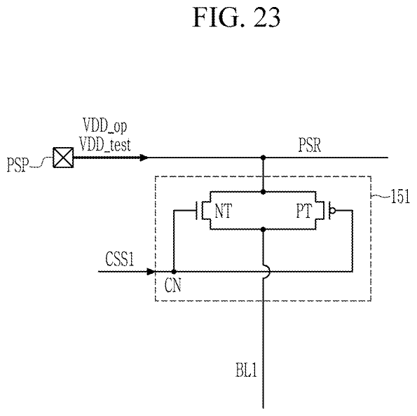

FIG. 23 is a circuit diagram illustrating a configuration of one of bitline select switches of FIG. 20 in more detail. Hereinafter, the configuration of the first bitline select switch 151 will be representatively described with reference to FIG. 23. However, the scope of the present disclosure is not limited thereto, and second to m-th bitline select switches 152 to 15m may also be implemented similarly.

Referring to FIGS. 1 to 23, the first bitline select switch 151 may be connected between the power supply rail PSR and the first bitline BL1.

The first bitline select switch 151 may include a first switch transistor NT and a second switch transistor PT. The first switch transistor NT and the second switch transistor PT may be connected in parallel between the power supply rail PSR and the first bitline BL1.

Gate terminals of the first switch transistor NT and the second switch transistor PT may be connected to a control node CN. The control node CN may receive the first column select signal CSS1. The first switch transistor NT and the second switch transistor PT may operate in response to the first column select signal CSS1.

For a more concise description, an embodiment in which the first switch transistor NT and the second switch transistor PT operate in response to a single first column select signal CSS1 will be representatively described. However, the scope of the present disclosure is not limited thereto, and the switch controller 160 may be implemented to individually control the first switch transistor NT and the second switch transistor PT through different control signals. That is, the scope of the present disclosure will not be limited to a specific method for the switch controller 160 to control the bitline selector 150.

When the test power source voltage VDD_test is provided from the power supply pad PSP, the first column select signal CSS1 may be logic high. In this case, the test power source voltage VDD_test may be provided to the first bitline BL1 through the first switch transistor NT. That is, when a test operation of the memory device 100 is performed, the test power source voltage VDD_test may be provided to the first bitline BL1 through the first switch transistor NT.

When the driving power source voltage VDD_op is provided from the power supply pad PSP, the first column select signal CSS1 may be logic low. In this case, the test power source voltage VDD_test may be provided to the first bitline BL1 through the second switch transistor PT. That is, when a program operation of the memory device 100 is performed, the driving power source voltage VDD_op may be provided to the first bitline BL1 through the second switch transistor PT.

In an embodiment, the first switch transistor NT may be implemented as an N-channel metal-oxide semiconductor (NMOS) transistor, and the second switch transistor PT may be implemented as a P-channel metal-oxide semiconductor (PMOS) transistor.

In this case, the driving power source voltage VDD_op, which is a relatively high voltage, may be provided to the first bitline BL1 through the PMOS transistor. On the contrary, the test power source voltage VDD_test, which is a relatively low voltage, may be provided to the first bitline BL1 through the NMOS transistor. Therefore, according to the embodiment of the present disclosure, the type of transistor used to connect between the first bitline BL1 and the power supply rail PSR may be optimized depending on the level of the voltage provided from the power supply pad PSP.

The contents described above are specific embodiments for implementing the present disclosure. The present disclosure may include not only the embodiments described above but also embodiments in which a design is simply or easily capable of being changed. In addition, the present disclosure may also include technologies easily changed to be implemented using embodiments. Therefore, the scope of the present invention should not be limited to the above embodiments, and should be defined by the equivalents of the following claims as well as the following claims.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Other words used to describe the relationship between elements should be interpreted in a like fashion (e.g., “between” versus “directly between.” “adjacent” versus “directly adjacent.” etc.).

What is claimed is:

1. A memory device, comprising:
a first memory cell including a first electrical fuse and a first program transistor connected in series between a first bitline and a ground voltage node;
a second memory cell including a second electrical fuse and a second program transistor connected in series between the first bitline and the ground voltage node; and
a first test cell including a first test transistor connected between the first bitline and the ground voltage node.

2. The memory device of claim 1, wherein:
the first program transistor operates in response to a voltage level of a first word line,
the second program transistor operates in response to a voltage level of a second word line, and
the first test transistor operates in response to a voltage level of a first dummy word line.

3. The memory device of claim 2, further comprising:
a second test cell including a second test transistor operating in response to a voltage level of a second dummy word line.

4. The memory device of claim 3, wherein:
the first bitline and a drain terminal of the first test transistor are electrically shorted to each other,
the first bitline and a drain terminal of the second test transistor are electrically isolated from each other.

5. The memory device of claim 4, configured to perform testing wherein:
the first word line is activated at a first time point,
the first dummy word line is activated at a second time point, and
the second dummy word line is activated at a third time point.

6. The memory device of claim 5, wherein during testing:
at the first time point, the first and second dummy word lines and the second word line are deactivated,
at the second time point, the first and second word lines and the second dummy word line are deactivated,
at the third time point, the first and second word lines and the first dummy word line are deactivated.

7. The memory device of claim 5, further comprising:
a power supply rail connected to a power supply pad; and
a first bitline select switch connected between the power supply rail and the first bitline,
wherein during testing the first bitline select switch is turned on at the first time point, the second time point, and the third time point.

8. The memory device of claim 7, wherein during the testing, the resistance value of the first electrical fuse is measured based on:
a first current provided to the power supply pad from an external device at the first time point;
a second current provided to the power supply pad from the external device at the second time point; and
a third current provided to the power supply pad from the external device at the third time point.

9. The memory device of claim 7, wherein the first bitline select switch comprises:
a N-channel metal-oxide semiconductor (NMOS) transistor connected between the first bitline and the power supply rail, and turned on at the first time point, the second time point, and the third time point.

10. The memory device of claim 1, wherein:
a size of the first test transistor corresponds to a size of the first program transistor.

11. A test system, comprising:
a memory device including a first memory cell connected to a first word line and a first bitline, a first test cell connected to a first dummy word line and the first bitline, and a power supply pad connected to the first bitline; and
a test device configured to measure a first current provided to the power supply pad in response to activation of the first word line and the first bitline, a second current provided to the power supply pad in response to activation of the first dummy word line and the first bitline, and a third current provided to the power supply pad in response to activation of the first bitline.

12. The test system of claim 11, wherein:
the first memory cell comprises a first program transistor and a first electrical fuse connected in series between the first bitline and a ground voltage, and
the first test cell comprises a first test transistor connected between the first bitline and the ground voltage,
wherein the first program transistor operates in response to a voltage level of the first word line, and the first test transistor operates in response to a voltage level of the first dummy word line.

13. The test system of claim 12, wherein the test device further comprises a second test cell connected to the first bitline and a second dummy word line.

14. The test system of claim 13, wherein the second test cell comprises:
a second test transistor including a gate terminal connected to the second dummy word line, a source terminal connected to the ground voltage, and a drain terminal not electrically connected to the first bitline.

15. The test system of claim 12, wherein the test device is configured to calculate a resistance value of the first electrical fuse based on the first to third currents.

16. The test system of claim 15, wherein the test device is configured to provide a first voltage to the power supply pad while measuring the first, second, and third currents.

17. The test system of claim 16, wherein:
the test device is configured to calculate the resistance value of the first electrical fuse based on the following equation,
$${R}_{target} = \frac{VDD\_test}{{I}_{A} - {I}_{C}} - \frac{VDD\_test}{{I}_{B} - {I}_{C}} \qquad ( Equation )$$
wherein the R_{target} represents resistance value of the first electrical fuse, the VDD_test represents the voltage level of the first voltage, the I_{A} represents the size of the first current, the I_{B} represents the size of the second current, and the I_{C} represents the size of the third current.

18. The test system of claim 12, wherein sizes of the first program transistor and the first test transistor correspond to each other.

19. A memory device, comprising:
a memory cell array including a plurality of memory cells connected to a first bitline; and
a test cell array including a first test cell and a second test cell connected to the first bitline,
wherein the first test cell comprises:
a first test transistor including a first drain terminal electrically connected to the first bitline, and a first source terminal connected to a ground voltage node,
wherein the second test cell comprises:
a second test transistor including a second drain terminal not electrically connected to the first bitline, and a second source terminal connected to the ground voltage node.

20. The memory device of claim 19, wherein:
the first test cell comprises:
a first bitline contact connected to the first bitline;
a first drain contact connected to the first drain terminal; and
a first conductor connected to the first bitline and the first drain contact through one or more vias, and
the second test cell comprises:
a second bitline contact connected to the first bitline;
a second drain contact connected to the second drain terminal;
a second conductor; and
an interlayer insulating layer electrically separating the second conductor, the second bitline contact, and the second drain contact.
